(19) United States
(12) Patent Application Publication
(10) Pub. No.: US 2025/0271308 A1
(43) Pub. Date: Aug. 28, 2025

(54) WAVELENGTH DETECTION DEVICE

(71) Applicant: FURUKAWA ELECTRIC CO., LTD., Tokyo (JP)

(72) Inventors: Go KOBAYASHI, Tokyo (JP); Yozo ISHIKAWA, Tokyo (JP); Noritaka MATSUBARA, Tokyo (JP); Atsushi IZAWA, Tokyo (JP); Atsushi KAJI, Tokyo (JP)

(73) Assignee: FURUKAWA ELECTRIC CO., LTD., Tokyo (JP)

(21) Appl. No.: 19/204,690

(22) Filed: May 12, 2025

Related U.S. Application Data
(63) Continuation of application No. PCT/JP2023/043659, filed on Dec. 6, 2023.

(30) Foreign Application Priority Data
Dec. 13, 2022 (JP) 2022-198349

(51) Int. Cl. G01J 9/00

(52) U.S. Cl. CPC G01J 9/00

(57) ABSTRACT

A wavelength detection device includes: waveguides configured to guide lights; a multiplexer unit configured to multiplex lights respectively guided through the waveguides and having wavelengths different from one another; a filter unit to which light output from the multiplexer unit is input, the filter unit having a property of having light transmittance that changes according to wavelength; and a detection unit configured to detect intensity of light output from the filter unit. The waveguides, the multiplexer unit, and the filter unit are included in a planar lightwave circuit.

### CROSS-REFERENCE TO RELATED APPLICATIONS

This application is a continuation of International Application No. PCT/JP2023/043659, filed on Dec. 6, 2023 which claims the benefit of priority of the prior Japanese Patent Application No. 2022-198349, filed on Dec. 13, 2022, the entire contents of which are incorporated herein by reference.

### BACKGROUND

The present disclosure relates to a wavelength detection device.

Wavelength detection devices (wavelength monitor units) to detect wavelengths of lights output from laser devices have been known conventionally (for example, International Publication No. WO 2020/166615).

### SUMMARY

Detecting a wavelength of a light output from a single light source by means of a single wavelength detection device is described in International Publication No. WO 2020/166615.

Enabling a wavelength detection device to be shared in an optical device having plural light sources that output lights of wavelengths different from one another would be beneficial, for example.

There is a need for a novel and improved wavelength detection device capable of being shared with respect to plural lights having wavelengths different from one another, for example.

According to one aspect of the present disclosure, there is provided a wavelength detection device including: waveguides configured to guide lights; a multiplexer unit configured to multiplex lights respectively guided through the waveguides and having wavelengths different from one another; a filter unit to which light output from the multiplexer unit is input, the filter unit having a property of having light transmittance that changes according to wavelength; and a detection unit configured to detect intensity of light output from the filter unit, wherein the waveguides, the multiplexer unit, and the filter unit are included in a planar lightwave circuit.

### BRIEF DESCRIPTION OF THE DRAWINGS

FIG. 1 is an exemplary and schematic plan view of a wavelength detection device according to a first embodiment;

FIG. 2 is an exemplary schematic diagram of a configuration of a multiplexer unit included in the wavelength detection device according to the first embodiment;

FIG. 3 is an exemplary graph illustrating relations between wavelength and transmittance in the multiplexer unit included in the wavelength detection device according to the first embodiment;

FIG. 4 is an exemplary and schematic plan view of a wavelength detection device according to a second embodiment;

FIG. 5 is an exemplary and schematic plan view of a wavelength detection device according to a third embodiment;

FIG. 6 is an exemplary and schematic plan view of a wavelength detection device according to a fourth embodiment;

FIG. 7 is an exemplary and schematic side view of part of the wavelength detection device according to the fourth embodiment; and

FIG. 8 is an exemplary and schematic plan view of a wavelength detection device according to a fifth embodiment.

### DETAILED DESCRIPTION

Exemplary embodiments will be disclosed hereinafter. Configurations of the embodiments and functions and results (effects) brought about by these configurations described hereinafter are just examples. The present disclosure may be implemented by configurations other than those disclosed hereinafter with respect to the embodiments. Furthermore, the present disclosure achieves at least one of various effects (including derivative effects) achieved by these configurations.

The embodiments described hereinafter have similar configurations. Therefore, the configurations of these embodiments achieve similar functions and effects based on the similar configurations. Furthermore, similar reference signs will hereinafter be assigned to such similar configurations and any redundant description thereof may be omitted.

Ordinals are assigned for convenience to distinguish between lights, wavelengths, and components in this specification, and thus neither indicate any priority or order of the lights, wavelengths, and components, nor limit the numbers of the lights, wavelengths, and components.

In each drawing, an X direction is represented by an arrow X, a Y direction is represented by an arrow Y, and a Z direction is represented by an arrow Z. The X direction, the Y direction, and the Z direction intersect one another and are orthogonal to one another. The Z direction may also be called a layering direction or a height direction.

Furthermore, each drawing is a diagram for illustration and scales and ratios in the drawings are not necessarily the same as the actual components.

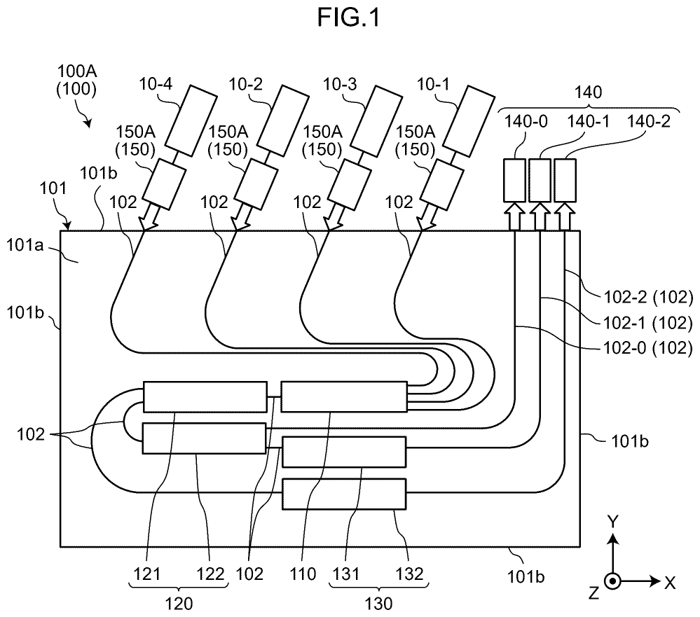

FIG. 1 is a plan view illustrating a schematic configuration of a wavelength detection device 100A (100) according to a first embodiment. The wavelength detection device 100 detects wavelengths of lights respectively output by laser devices 10-1 to 10-4 serving as light sources.

The laser devices 10-1 to 10-4 output lights having wavelengths different from one another. The laser devices 10-1 to 10-4 each include, for example, a semiconductor laser element that outputs a light according to electric current supplied to the semiconductor laser element.

In this embodiment, the laser device 10-1 outputs a light having a center wavelength of λ1. The laser device 10-2 outputs a light having a center wavelength of λ2 longer than λ1. The laser device 10-3 outputs a light having a center wavelength of λ3 longer than λ2. The laser device 10-4 outputs a light having a center wavelength of λ4 longer than λ3.

The wavelength detection device 100 includes a planar lightwave circuit (PLC) 101, plural switches 150A (150), and a detection unit 140.

The switches 150 have been respectively provided correspondingly to the laser devices 10-1 to 10-4. The switches 150 are each capable of switching between a state where light is transmitted therethrough and a state where transmission of light therethrough is lessened. The switches 150A may be configured as, for example, gate switches of the laser devices 10-1 to 10-4. The switches 150 are each an example of a switch unit.

The planar lightwave circuit 101 includes plural waveguides 102, a multiplexer unit 110, a splitter unit 120, and a filter unit 130. The planar lightwave circuit 101 has a substrate, and a layered portion layered on the substrate. Furthermore, the planar lightwave circuit 101 is made of, for example, a silica-based glass material or a silicon-based material.

Lights output from the laser devices 10-1 to 10-4 are respectively input to the waveguides 102 different from one another via the switches 150. In this embodiment, for example, the lights output from the four laser devices 10-1 to 10-4 are input to the four waveguides 102.

The waveguides 102 each include a core and cladding surrounding the core and guide light through the core. FIG. 1 illustrates the cores of the waveguides 102 in lines.

The multiplexer unit 110 multiplexes the lights input from the laser devices 10-1 to 10-4 and transmitted through the waveguides 102, that is, the plural lights having wavelengths different from one another. In this embodiment, the multiplexer unit 110 is capable of multiplexing the four lights guided through the four waveguides 102 and having the wavelengths different from one another. A detailed configuration of the multiplexer unit 110 will be described later.

The splitter unit 120 splits a light output from the multiplexer unit 110 into plural waveguides 102. In this embodiment, the splitter unit 120 has splitters 121 and 122, and these splitters 121 and 122 are each configured as a 1×2 splitter. The splitter unit 120 splits the light output from the multiplexer unit 110 into three waveguides 102.

Lights passing through two waveguides 102 of the three waveguides 102 are output from the planar lightwave circuit 101 through the filter unit 130 and a light passing through the remaining one waveguide 102 (102-0) of the three waveguides 102 is output from the planar lightwave circuit 101 without going through the filter unit 130.

The filter unit 130 has filters 131 and 132. The filters 131 and 132 each have a property of having light transmittance that changes according to wavelength, that is, a periodic property or a property of having transmittance that is maximized at a single specific wavelength (peak wavelength) and that decreases as the wavelength changes from the peak wavelength.

Furthermore, these properties of the filters 131 and 132, that is, their properties for transmittance in relation to wavelength are different from each other. For example, the filters 131 and 132 may be configured so that the wavelength, at which the rate of change in the transmittance in relation to the wavelength is maximized in one of the filters 131 and 132, is approximately the same as the peak wavelength of the other one of the filters 131 and 132. The filters 131 and 132 may each be configured as, for example, a ring resonator or a Mach-Zehnder interferometer.

A light that has passed through the filter 131 passes through the waveguide 102 (102-1) and is output from the planar lightwave circuit 101, and a light that has passed through the filter 132 passes through the waveguide 102 (102-2) and is output from the planar lightwave circuit 101.

Detection units 140-0 to 140-2 respectively detect intensities of the lights that have passed through the waveguides 102-0 to 102-2. The detection units 140-0 to 140-2 may be configured as, for example, photodiodes.

For this configuration of the detection units 140-0 to 140-2, a control unit not illustrated in the drawings is capable of detecting a wavelength of a light on the basis of a ratio (intensity ratio) of the intensity of the light detected by the detection unit 140-1 to the intensity of the light detected by the detection unit 140-0 and a ratio (intensity ratio) of the intensity of the light detected by the detection unit 140-2 to the intensity of the light detected by the detection unit 140-0.

Configurations of the splitter unit 120, the filter unit 130, and the detection unit 140 are not limited to the configurations in FIG. 1 and may be implemented by any of various modifications. For example, the number of the filter units 130 may be one and the number of the detection units 140 may be one or two.

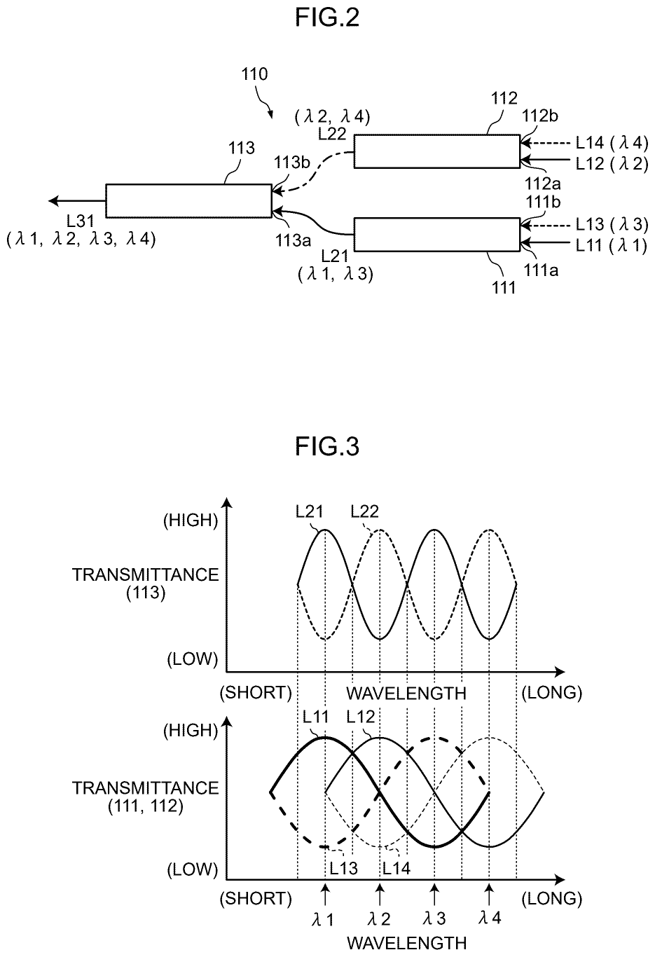

FIG. 2 is an exemplary schematic diagram of a configuration of the multiplexer unit 110. As illustrated in FIG. 2, the multiplexer unit 110 in this embodiment is configured to have three wavelength division multiplexing couplers 111, 112, and 113.

A light L11 from the laser device 10-1 is input to a port 111a of the wavelength division multiplexing coupler 111 and a light L13 from the laser device 10-3 is input to a port 111b of the wavelength division multiplexing coupler 111. The wavelength division multiplexing coupler 111 is capable of multiplexing the light L11 and the light L13. The light L11 is an example of a first light, and the light L13 is an example of a third light.

A light L12 from the laser device 10-2 is input to a port 112a of the wavelength division multiplexing coupler 112 and a light L14 from the laser device 10-4 is input to a port 112b of the wavelength division multiplexing coupler 112. The wavelength division multiplexing coupler 112 is capable of multiplexing the light L12 and the light L14. The light L12 is an example of a second light, and the light L14 is an example of a fourth light.

A light L21 output from the wavelength division multiplexing coupler 111 is input to a port 113a of the wavelength division multiplexing coupler 113, and a light L22 output from the wavelength division multiplexing coupler 112 is input to a port 113b of the wavelength division multiplexing coupler 113. The wavelength division multiplexing coupler 113 is capable of multiplexing the light L21 and the light L22.

FIG. 3 is a graph illustrating characteristics of wavelength and transmittance in the three wavelength division multiplexing couplers 111, 112, and 113. The lower part of the graph illustrates characteristics of the wavelength division multiplexing couplers 111 and 112 and the upper part of the graph illustrates characteristics of the wavelength division multiplexing coupler 113.

In the lower part of the graph in FIG. 3, wavelength-transmittance characteristics of the wavelength division multiplexing coupler 111 are represented by a bold solid line and a bold broken line, the bold solid line represents the wavelength-transmittance characteristics for the light input to the port 111a, and the solid broken line represents the wavelength-transmittance characteristics for the light input to the port 111b. As illustrated by these bold solid line and bold broken line, the wavelength division multiplexing coupler 111 is configured so that the transmittance changes sinusoidally in relation to the wavelength. The wavelength division multiplexing coupler 111 is configured so that the transmittance is maximized (at its top peak) at the wavelength of λ1 and the transmittance is minimized (at its bottom peak) at the wavelength of λ3, with respect to the light input to the port 111a. Furthermore, the wavelength division multiplexing coupler 111 is configured so that the transmittance is minimized (at its bottom peak) at the wavelength of λ1 and the transmittance is maximized (at its top peak) at the wavelength of λ3, with respect to the light input to the port 111b. Inputting the light L11 having the center wavelength of λ1 to the port 111a and inputting the light L13 having the center wavelength of λ3 to the port 111b in this configuration enable waveguides to be formed, the waveguides being where losses are small for both of the light L11 and the light L13 in the wavelength division multiplexing coupler 111.

In the lower part of the graph in FIG. 3, wavelength-transmittance characteristics of the wavelength division multiplexing coupler 112 are represented by a thin solid line and a thin broken line, the thin solid line represents the wavelength-transmittance characteristics for the light input to the port 112a, and the thin broken line represents the wavelength-transmittance characteristics for the light input to the port 112b. As illustrated by these thin solid line and thin broken line, the wavelength division multiplexing coupler 112 is configured so that the transmittance changes sinusoidally in relation to the wavelength. The wavelength division multiplexing coupler 112 is configured so that the transmittance is maximized (at its top peak) at the wavelength of λ2 and the transmittance is minimized (at its bottom peak) at the wavelength of λ4, with respect to the light input to the port 112a. Furthermore, the wavelength division multiplexing coupler 112 is configured so that the transmittance is minimized (at its bottom peak) at the wavelength of λ2 and the transmittance is maximized (at its top peak) at the wavelength of λ4, with respect to the light input to the port 112b. Inputting the light L12 having the center wavelength of λ2 to the port 112a and inputting the light L14 having the center wavelength of λ4 to the port 112b in this configuration enable waveguides to be formed, the waveguides being where losses are small for both of the light L12 and the light L14 in the wavelength division multiplexing coupler 112.

Furthermore, in the top part of the graph in FIG. 3, wavelength-transmittance characteristics of the wavelength division multiplexing coupler 113 are represented by a solid line and a broken line, the solid line represents the wavelength-transmittance characteristics for the light input to the port 113a, and the broken line represents the wavelength-transmittance characteristics for the light input to the port 113b. As illustrated by these solid line and broken line, the wavelength division multiplexing coupler 113 is configured so that the transmittance changes sinusoidally and periodically in relation to the wavelength. The wavelength division multiplexing coupler 113 is configured so that the transmittance is maximized (at its top peak) at the wavelengths of λ1 and λ3 and the transmittance is minimized (at its bottom peak) at the wavelengths of λ2 and λ4, with respect to the light input to the port 113a. Furthermore, the wavelength division multiplexing coupler 113 is configured so that the transmittance is maximized (at its top peak) at the wavelengths of λ2 and λ4 and the transmittance is minimized (at its bottom peak) at the wavelengths of λ1 and λ3, with respect to the light input to the port 113b. In this configuration, inputting the light L21 including the light L11 having the center wavelength of λ1 and the light L13 having the center wavelength of λ3 to the port 113a, the light L11 and the light L13 both having been output from the wavelength division multiplexing coupler 111, and inputting the light L22 including the light L12 having the center wavelength of λ2 and the light L14 having the center wavelength of λ4 to the port 113b, the light L12 and the light L14 both having been output from the wavelength division multiplexing coupler 112, enable waveguides to be formed, the waveguides being where losses are small for both of the light L21 and the light L22, that is, for the light L11, the light L12, the light L13, and the light L14, in the wavelength division multiplexing coupler 113.

As described above, in this embodiment, the wavelength detection device 100 includes the multiplexer unit 110 that multiplexes the plural lights L11 to L14 having wavelengths different from one another, and the configuration of the splitter unit 120, the filter unit 130, and the detection unit 140 is thus able to be shared by the plural lights L11 to L14. Therefore, an effect achieved by this embodiment is, for example, that the wavelength detection device 100 is able to be downsized and the labor and cost required in manufacture of the wavelength detection device 100 are able to be reduced, as compared to a configuration including the splitter unit 120, the filter unit 130, and the detection unit 140, for each of plural lights having different wavelengths.

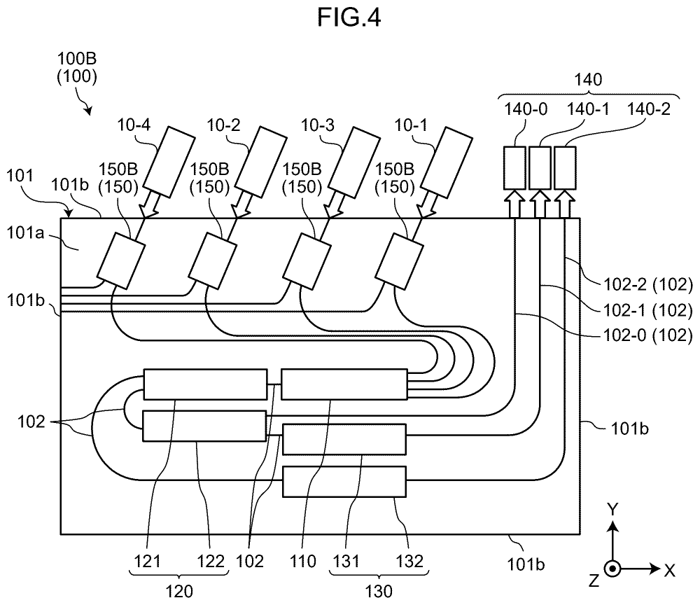

FIG. 4 is a plan view illustrating a schematic configuration of a wavelength detection device 100B (100) according to a second embodiment. The wavelength detection device 100B according to this embodiment includes switches 150B (150) in a planar lightwave circuit 101, instead of the switches 150A outside the planar lightwave circuit 101 included in the wavelength detection device 100A according to the first embodiment. These switches 150B may each be configured as, for example, a variable optical attenuator (VOA).

The wavelength detection device 100B according to this embodiment has a configuration similar to that of the wavelength detection device 100A according to the first embodiment, except that the switches 150 are different. An effect similar to that of the first embodiment is also able to be achieved by this embodiment.

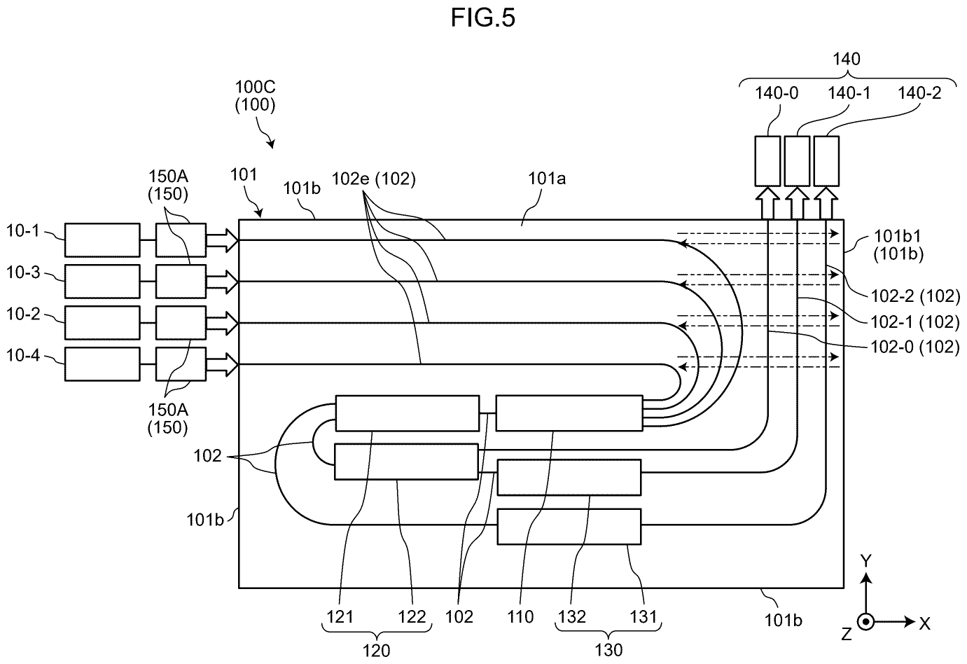

FIG. 5 is a plan view illustrating a schematic configuration of a wavelength detection device 100C (100) according to a third embodiment. The wavelength detection device 100C according to this embodiment has a configuration similar to that of the wavelength detection device 100A according to the first embodiment. Therefore, this embodiment also achieves an effect similar to that of the first embodiment.

However, routes of waveguides 102 in the wavelength detection device 100C according to this embodiment are different from those in the first embodiment and the second embodiment.

Specifically, firstly, lights input from laser devices 10-1 to 10-4 are respectively guided through intervals 102e of the waveguides 102, the intervals 102e linearly extending in the X direction, and a multiplexer unit 110, a splitter unit 120, and a filter unit 130 are positioned off extension lines (dashed and double-dotted arrows in the X direction in FIG. 5) of these intervals 102e. The intervals 102e are each an example of an extending portion.

Furthermore, the multiplexer unit 110, the splitter unit 120, and the filter unit 130 are positioned off routes that virtual reflected lights travel through (dashed and doubled-dotted arrows heading in a direction opposite to the X direction in FIG. 5), the virtual reflected lights resulting from reflection of virtual stray lights at a side surface 101b1 (101b) of a planar lightwave circuit 101, the virtual stray lights having leaked out from the intervals 102e and traveled along the extension lines of the intervals 102e.

This embodiment configured as described able enables reduction in obstruction to detection of intensities by a detection unit 140 and thus to detection of wavelengths by the wavelength detection device 100, the obstruction resulting from coupling of the stray lights leaking out from the intervals 102e and the lights resulting from reflection of the stray lights at the side surface 101b1 to the multiplexer unit 110, the splitter unit 120, and the filter unit 130.

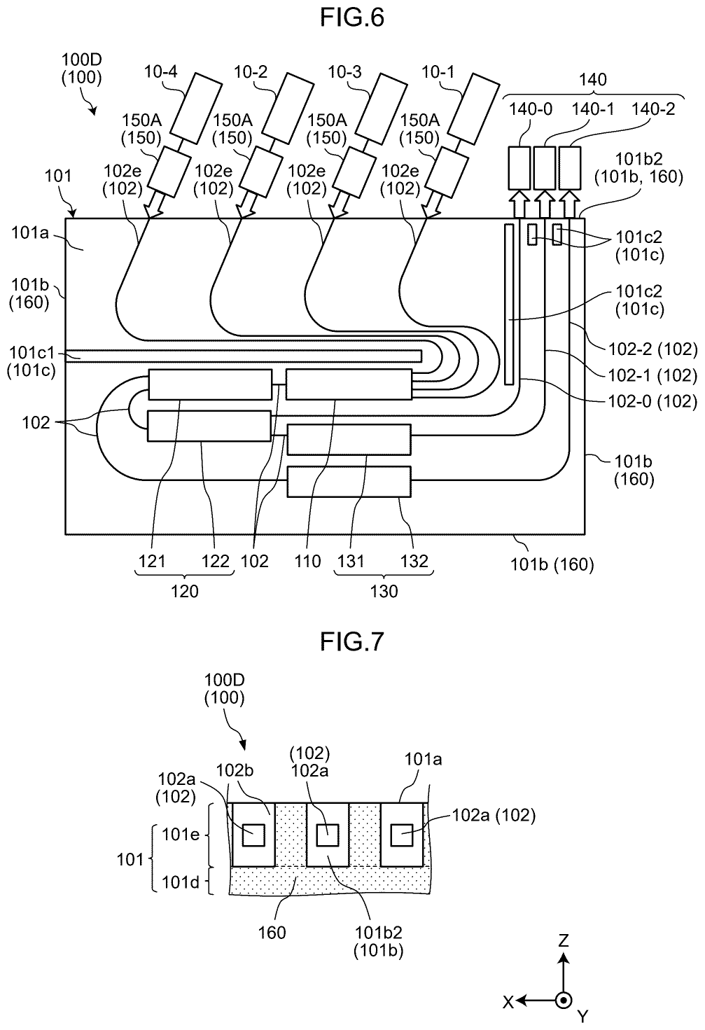

FIG. 6 is a plan view illustrating a schematic configuration of a wavelength detection device 100D (100) according to a fourth embodiment. The wavelength detection device 100D according to this embodiment has a configuration similar to that of the wavelength detection device 100A according to the first embodiment. Therefore, this embodiment also achieves an effect similar to that of the first embodiment.

However, spaces 101c have been provided at positions off waveguides 102 of a planar lightwave circuit 101 in the wavelength detection device 100D according to this embodiment. The spaces 101c have been formed of, for example, openings open on a top surface 101a positioned at an end of the planar lightwave circuit 101, the end being in the Z direction. The spaces 101c may also be referred to as grooves or recessed portions.

The spaces 101c may be provided at various positions off the waveguides 102. The spaces 101c enable reduction in propagation of stray lights in the planar lightwave circuit 101.

A space 101c1 of the spaces 101c is positioned between: a multiplexer unit 110, a splitter unit 120, and a filter unit 130; and intervals 102e of the waveguides 102 where lights output from laser devices 10-1 to 104 and input to the planar lightwave circuit 101 via switches 150 are guided through. This configuration enables, by means of the space 101c1, blocking of stray lights leaking out from the intervals 102e and thus enables reduction in obstruction to detection of intensities by a detection unit 140 and thus to detection of wavelengths by the wavelength detection device 100, the obstruction resulting from coupling of the stray lights to the multiplexer unit 110, the splitter unit 120, and the filter unit 130.

Spaces 101c2 of the spaces 101c are provided between the waveguides 102, near a side surface 101b2 of the planar lightwave circuit 101, the side surface 101b2 being where lights are output. This configuration enables reduction in propagation of light in the planar lightwave circuit 101 in a case where the light has entered the planar lightwave circuit 101, the light being returned light to the side surface 101b2 from outside, for example, reflected light from the detection unit 140, the reflected light resulting from reflection of the output light.

Furthermore, in this embodiment, an absorption layer 160 that absorbs light has been provided to cover side surfaces 101b of the planar lightwave circuit 101, the side surfaces 101b being end faces extending in directions intersecting the Z direction (the X direction and Y direction). The absorption layer 160 is, for example, a black paint film. The absorption layer 160 enables reduction in reflection of stray lights at the side surfaces 101b, the stray lights having propagated through the planar lightwave circuit 101, and also enables reduction in entrance of light into the planar lightwave circuit 101 via the side surfaces 101b from the outside. The absorption layer 160 is, for example, an example of an absorption portion.

FIG. 7 is a side view of a region near output ends of the waveguides 102 of the planar lightwave circuit 101 according to this embodiment. As illustrated in FIG. 7, the planar lightwave circuit 101 includes a substrate 101d, and a layered portion 101e formed on the substrate 101d. Cores 102a and cladding 102b have been formed in the layered portion 101e. As illustrated in FIG. 7, the absorption layer 160 is provided to cover part of the side surface 101b2, the part excluding the cores 102a and a portion of the cladding 102b that are at the output ends of the waveguides 102. This configuration prevents the absorption layer 160 from hindering transmission of proper lights in the waveguides 102.

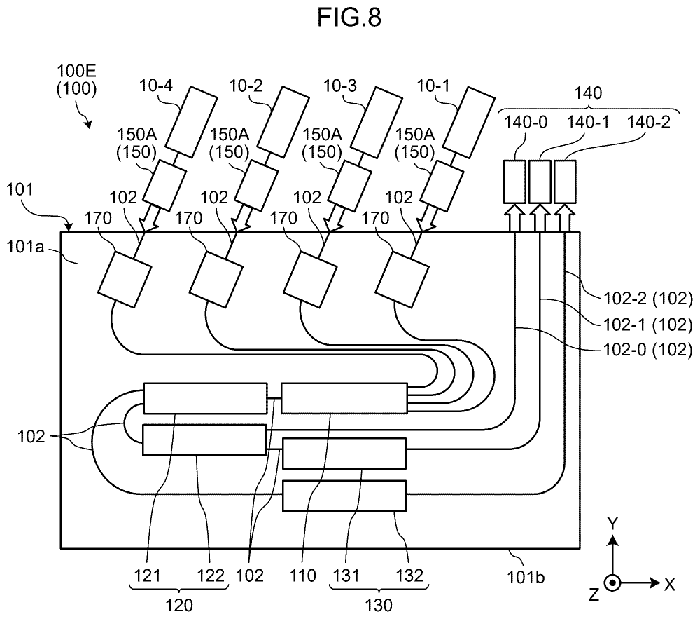

FIG. 8 is a plan view illustrating a schematic configuration of a wavelength detection device 100E (100) according to a fifth embodiment. The wavelength detection device 100E according to this embodiment has a configuration similar to that of the wavelength detection device 100A according to the first embodiment. Therefore, this embodiment also achieves an effect similar to that of the first embodiment.

However, mode filters 170 that limit propagation modes of lights guided through waveguides 102 have been provided in a planar lightwave circuit 101 in the wavelength detection device 100E according to this embodiment. The mode filters 170 enable reduction in propagation of lights in higher-order modes and thus enable reduction in leakage of lights from the waveguides 102 and thus in generation of stray lights. Therefore, this configuration enables reduction in obstruction to detection of intensities by a detection unit 140 and thus to detection of wavelengths by the wavelength detection device 100, the obstruction resulting from coupling of the stray lights to a multiplexer unit 110, a splitter unit 120, and a filter unit 130.

The present disclosure enables, for example, a novel and improved wavelength detection device to be obtained, the novel and improved wavelength detection device being capable of being shared with respect to plural lights having wavelengths different from one another.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wavelength detection device comprising:
waveguides configured to guide lights;
a multiplexer unit configured to multiplex lights respectively guided through the waveguides and having wavelengths different from one another;
a filter unit to which light output from the multiplexer unit is input, the filter unit having a property of having light transmittance that changes according to wavelength; and
a detection unit configured to detect intensity of light output from the filter unit, wherein
the waveguides, the multiplexer unit, and the filter unit are included in a planar lightwave circuit.

2. The wavelength detection device according to claim 1, further comprising switch units respectively provided correspondingly to the lights and configured to switch between a state where the light is transmitted therethrough and a state where transmission of the light therethrough is lessened.

3. The wavelength detection device according to claim 1, wherein the multiplexer unit includes a wavelength division multiplexing coupler.

4. The wavelength detection device according to claim 3, wherein
the lights include a first light having a center wavelength at a first wavelength, a second light having a center wavelength at a second wavelength longer than the first wavelength, a third light having a center wavelength at a third wavelength longer than the second wavelength, and a fourth light having a center wavelength at a fourth wavelength longer than the third wavelength, and
the wavelength division multiplexing coupler includes:
a first wavelength division multiplexing coupler including a port where the first light is input and transmittance of light input to the port peaks at the first wavelength, and a port where the third light is input and transmittance of light input to the port peaks at the third wavelength;
a second wavelength division multiplexing coupler including a port where the second light is input and transmittance of light input to the port peaks at the second wavelength, and a port where the fourth light is input and transmittance of light input to the port peaks at the fourth wavelength; and
a third wavelength division multiplexing coupler including a port where output light from the first wavelength division multiplexing coupler is input and transmittance of light input to the port peaks at the first wavelength and the third wavelength, and a port where output light from the second wavelength division multiplexing coupler is input and transmittance of light input to the port peaks at the second wavelength and the fourth wavelength.

5. The wavelength detection device according to claim 1, wherein the filter unit includes filters having different properties for transmittance in relation to wavelength.

6. The wavelength detection device according to claim 1, wherein
the waveguides include extending portions extending linearly, and
the multiplexer unit and the filter unit are positioned off extension lines of the extending portions.

7. The wavelength detection device according to claim 1, wherein
the waveguides have extending portions extending linearly, and
the multiplexer unit and the filter unit are positioned off routes that virtual reflected lights travel along, the virtual reflected lights resulting from reflection of virtual stray lights by a side surface of the planar lightwave circuit, the virtual stray lights having leaked out from the extending portions and traveled along extension lines of the extending portions.

8. The wavelength detection device according to claim 1, further comprising a space provided in part of the planar lightwave circuit, the part being off the waveguides.

9. The wavelength detection device according to claim 1, further comprising an absorption portion configured to cover a side surface of the planar lightwave circuit and absorb light.

10. The wavelength detection device according to claim 1, further comprising a mode filter configured to limit propagation modes of a light guided through the waveguides.
